(19) United States
(12) Patent Application Publication
(10) Pub. No.: US 2016/0358808 A1
(43) Pub. Date: Dec. 8, 2016

(54) HYBRID 200 MM/300 MM SEMICONDUCTOR PROCESSING APPARATUSES

(71) Applicant: Lam Research Corporation, Fremont, CA (US)

(72) Inventors: Eric Russell Madsen, Aloha, OR (US); Narudha Tai Ben-Yuhmin, Santa Clara, CA (US); Michael Christensen, Tualatin, OR (US); Chris Erick Karlsrud, Chandler, AZ (US); Joseph Hung-chi Wei, Portland, OR (US); Linh Hoang, Alameda, CA (US); Alasdair Dent, San Jose, CA (US)

(21) Appl. No.: 15/169,576

(22) Filed: May 31, 2016

Related U.S. Application Data
(60) Provisional application No. 62/170,067, filed on Jun. 2, 2015.

(51) Int. Cl. H01L 21/687; C23C 16/455; C23C 16/458; C23C 16/50

(52) U.S. Cl. CPC H01L 21/68771; H01L 21/68735; H01L 21/68757; H01L 21/68792; C23C 16/50; C23C 16/45565; C23C 16/458

(57) ABSTRACT

In one aspect, several apparatuses are described that allow a processing chamber designed for plasma-enhanced chemical vapor deposition on 300 mm wafers to be performed on 200 mm wafers. More specifically, a modified pedestal, carrier plate, and showerhead are described that have been designed for 200 mm wafers and are compatible with 300 mm wafer processing chambers. It has further been observed that deposited films using the modified 200 mm apparatuses are comparable in quality with films deposited with the 300 mm devices they replace.

### CROSS REFERENCE TO RELATED APPLICATIONS

This application claims benefit of priority under 35 U.S.C. §119(e) to U.S. Provisional Application No. 62/170,067, filed on Jun. 2, 2015, and titled “HYBRID 200MM/300MM SEMICONDUCTOR PROCESSING APPARATUS,” which is hereby incorporated by reference herein in its entirety.

### BACKGROUND

Semiconductor processing is used to fabricate the integrated circuits present in every day electrical and electronic devices. Typically, semiconductor devices are fabricated on nearly defect free single crystalline wafers, such as silicon, that are provided in certain industry-standard sizes, such as wafers having 150 mm, 200 mm, or 300 mm diameters. It has been proposed that eventually a 450 mm wafer size will be adopted further reduce costs of mass-produced semiconductor devices.

Semiconductor manufacturing tools are currently designed to accommodate a single semiconductor wafer size, e.g., a 200 mm or 300 mm diameter semiconductor wafer. The size of the semiconductor wafer that is to be processed in a given semiconductor processing chamber may drive a number of parameters that define various aspects of the chamber. A semiconductor processing chamber that is designed to accommodate 200 mm diameter semiconductor wafers will be unsuitable for processing 300 mm semiconductor wafers, and vice versa. For example, a semiconductor processing chamber sized for 200 mm semiconductor wafers may be too small to fit a 300 mm semiconductor wafer. At the same time, a semiconductor processing chamber sized for 300 mm semiconductor wafers may have systems that, while perfectly suitable for use in processing 300 mm semiconductor wafers, cause non-uniformities in 200 mm semiconductor wafers. For example, if the showerhead of a PECVD apparatus is much larger in diameter than a 200 mm wafer, the resulting deposition will not be uniform.

Manufacturing semiconductors is an extremely complicated and expensive process that is, from a practical sense, only economically viable if the volume of semiconductor devices that is produced is sufficiently high. Thus, the semiconductor manufacturing industry is inordinately focused on efficiency and yield—the more semiconductor wafers that can be processed in a given processing facility, also referred to in the industry as a “fab,” the better. As such, semiconductor manufacturers typically seek to maximize the number of semiconductor processing tools that can be fit within a given facility, thereby maximizing the number of semiconductor wafers that may be processed simultaneously within the facility and increasing yield. In response to this desire, semiconductor processing tool manufacturers generally seek to reduce or minimize semiconductor processing tool footprint (the facility space or volume that is needed to house, maintain, and use a given semiconductor processing tool) to allow more semiconductor processing tools per unit of floor space to be installed in a given fab. Perhaps the biggest driver in determining the overall size and footprint of a semiconductor processing tool is the size of the wafer that the semiconductor processing tool is designed to process. The wafer size will ultimately dictate the minimum size of the processing chamber, the size of the loadlocks that are used, and various other key parameters that affect the overall size of the tool. Generally speaking, semiconductor processing tool manufacturers will attempt to design a semiconductor processing tool such that it is, from a practical perspective, as small as is economically and technically feasible for the wafer size that is to be processed in the tool.

### SUMMARY

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale unless specifically indicated as being scaled drawings.

In some implementations, an apparatus for carrying semiconductor wafers is provided. The apparatus may be designed to carry 200 mm semiconductor wafers but be compatible with the wafer handling features of a 300 mm semiconductor processing tool. The apparatus may include an annular ring that is between 1 mm and 10 mm thick and that has an outer diameter greater than 300 mm and an inner diameter less than 200 mm. The annular ring may also include one or more recesses in a first side and have a second side opposite the first side that is configured to support the semiconductor wafer.

In some implementations of the apparatus, the thickness of the annular ring may be less than 5 mm. In some other or alternative such implementations, the annular ring may further include a circular recess in the second side, and the circular recess and the annular ring may be coaxial and the circular recess may have a diameter greater than 200 mm. In some such implementations, the circular recess may have a depth that is between 0.5 mm and 1.5 mm. In some alternative or further such implementations, the circular recess may have a diameter greater than 200 mm and less than 210 mm.

The apparatus may, in some implementations, be made of a ceramic material such as aluminum oxide, silicon oxide, silicon carbide, silicon nitride, or aluminum nitride.

In some implementations, the one or more recesses may have annular sector shapes.

In some implementations, the outer diameter of the annular ring may be between 360 mm and 390 mm.

In some implementations, the thickness of the annular ring in the one or more recesses may be less than 50% of the thickness of the annular ring in locations adjacent to the one or more recesses.

In some implementations, a showerhead apparatus for distributing gases over the surface of a 200 mm diameter semiconductor wafer and that is configured to interface with showerhead support features for supporting a different showerhead apparatus for distributing gases over the surface of a 300 mm diameter semiconductor wafer may be provided. The showerhead apparatus may include an inlet configured to connect to a gas source, a stem with an interior gas passage, and a showerhead plenum. The interior gas passage may fluidically connect the inlet with the showerhead plenum. The showerhead plenum may have an outer diameter between 189 mm and 265 mm, thereby configuring the showerhead plenum to process 200 mm semiconductor wafers, and the stem may have a cylindrical portion with an exterior diameter that is sized to interface with a mechanical interface of a semiconductor processing tool and the mechanical interface may also be sized to interface with a different showerhead configured to process 300 mm semiconductor wafers.

In some such implementations of the showerhead apparatus, the stem may have an exterior diameter of between 30 mm and 38 mm. In some further or additional such implementations, the stem may have a tapered portion interposed between the showerhead plenum and the cylindrical portion and the stem may taper from a nominal exterior diameter of between 30 mm and 38 mm in the cylindrical portion to a diameter of between 16 mm and 24 mm.

In some implementations of the showerhead apparatus, the interior gas passage diameter may be between 5 mm and 10 mm.

In some implementations, a semiconductor wafer processing tool is provided. The semiconductor processing tool may include a chamber having one or more semiconductor processing stations. At least one of the semiconductor processing stations may have a pedestal and a showerhead. The pedestal may have a raised wafer support surface with an outer diameter of less than 200 mm and greater than 150 mm. The chamber may also include one or more load ports, and each load port may be configured to allow 300 mm semiconductor wafers to be inserted into or withdrawn from the chamber, located in a wall of the chamber, and have a width greater than 300 mm.

In some such implementations of the semiconductor processing tool, the pedestal may have an outer diameter of at least 300 mm and the showerhead may have an outer diameter between 50% and 70% of the pedestal outer diameter.

In some implementations of the semiconductor processing tool, the pedestal and the showerhead may be swappable with a second pedestal and a second showerhead. The second pedestal may have an outer diameter of at least 300 mm and a raised wafer support surface with an outer diameter of less than 300 mm and greater than 250 mm, and the second showerhead may have an outer diameter that is 80% or more of the pedestal outer diameter. In such implementations, installing the second pedestal and the second showerhead in one or more of the semiconductor processing stations may configure, at least in part, those semiconductor processing stations to process 300 mm diameter wafers.

In some implementations, the chamber may further include a rotational indexer shaft and a rotational indexer. The rotational indexer shaft may be configured to rotate the rotational indexer within the chamber, thereby allowing semiconductor wafers to be transferred from station to station within the chamber.

In some implementations of the semiconductor processing tool, the semiconductor processing tool may further include an annular ring that is between 1 mm and 10 mm thick and that has an outer diameter greater than 300 mm and an inner diameter less than 200 mm. In such implementations, each annular ring may have one or more recesses in a first side of the annular ring.

In some implementations, each pedestal may have an outer diameter of between 360 mm and 390 mm. In some alternative or additional such implementations, the showerhead may have an outer diameter of between 189 mm and 265 mm.

These and other implementations are described in further detail with reference to the Figures and the detailed description below.

### BRIEF DESCRIPTION OF THE DRAWINGS

FIG. 1 depicts a typical deposition system used for chemical vapor deposition.

FIG. 2 depicts various views of a carrier ring for 300 mm wafers.

FIG. 3 depicts a pedestal designed for 300 mm wafers.

FIG. 4 is an isometric cutaway view of a showerhead for 300 mm wafers.

FIG. 5 is a section view of the showerhead of FIG. 4.

FIGS. 6 and 7 provide sectional views of a processing chamber with an indexer that is in its lowered and raised positions, respectively.

FIG. 8 depicts a carrier ring for 200 mm wafers designed to be used with a processing chamber designed for 300 mm wafers.

FIG. 9 depicts a pedestal designed for handling 200 mm wafers in a processing chamber designed for 300 mm wafers.

FIG. 10 is an exploded view depicting how a pedestal and carrier ring, which are designed for use with a 200 mm wafer in a processing tool designed for 300 mm wafers, interface with each other and the wafer.

FIG. 11 is a view depicting how a pedestal and carrier ring, which are designed for use with a 200 mm wafer in a processing tool designed for 300 mm wafers, interface with each other and the wafer.

FIG. 12 depicts a four-station arrangement of pedestals in which the indexer has been lowered leaving the carrier rings resting on the respective pedestals.

FIG. 13 depicts a four-station arrangement of pedestals in which the indexer has been lifted up, allowing the indexer to rotate and move carrier rings and their respective wafers between stations.

FIG. 14 is a cutaway view of a showerhead designed for use with 200 mm wafers in a semiconductor processing tool that is designed for use with 300 mm wafers.

FIG. 15 is a section view of the showerhead of FIG. 14.

FIGS. 16 and 17 show isometric and exploded views that depict how 200 mm or 300 mm stations may be arranged in a four-station processing chamber designed for processing 300 mm wafers.

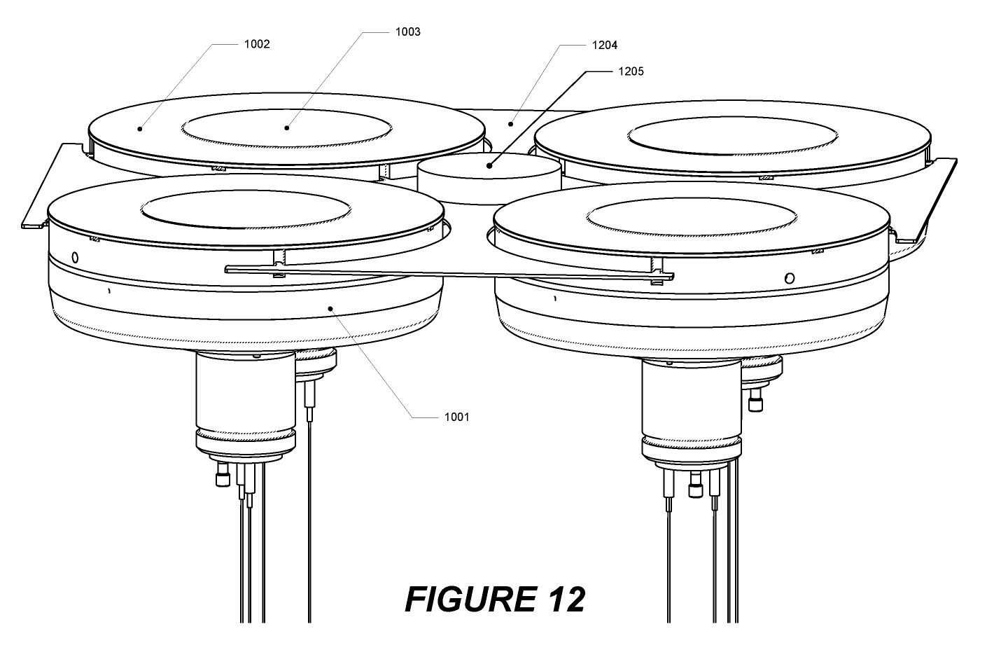

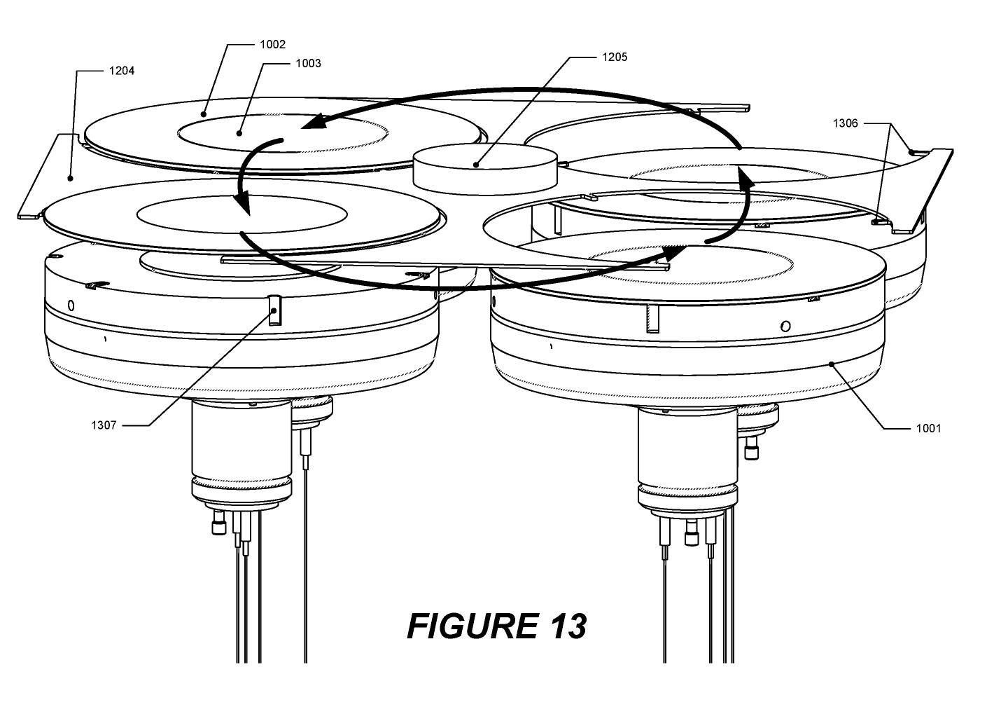

Each of the figures is drawn to scale within each Figure, with the exception of FIGS. 12 and 13.

### DETAILED DESCRIPTION

The following description includes certain details to provide context and/or full illustration of the various recited embodiments. It is to be understood, however, that the concepts discussed herein may be practiced or implemented without some or all of these details. Thus, while some disclosed embodiments are described with respect to various specific operations and/or features, it is to be understood that this disclosure is not limited to only these operations and/or features. Furthermore, in some instances, well-known operations and/or features are not described in detail to in the interests of conciseness.

The present inventors have determined that providing a plasma-enhanced chemical vapor deposition (PECVD) semiconductor processing tool that is capable of processing both 300 mm and 200 mm semiconductor wafers provides a unique capability not currently available in today's market. The processing tool in question may utilize a process chamber and pedestal that are sized to accommodate a 300 mm semiconductor wafer. Various components of the tool are configured to be replaceable or swappable in order to switch the tool between a configuration suitable for processing 300 mm semiconductor wafers and a configuration suitable for processing 200 mm semiconductor wafers, or vice versa. Components that are intended to process 200 mm wafers may be prefaced with “200 mm,” e.g., the 200 mm showerhead, and components that are intended to process 300 mm wafers may be prefaced with “300 mm,” e.g., the 300 mm carrier ring. These qualifiers are not intended to indicate that the components themselves have such dimensions (with the exception of the 200 mm and 300 mm wafers), just that these components are specifically intended to be used with wafers of the indicated size.

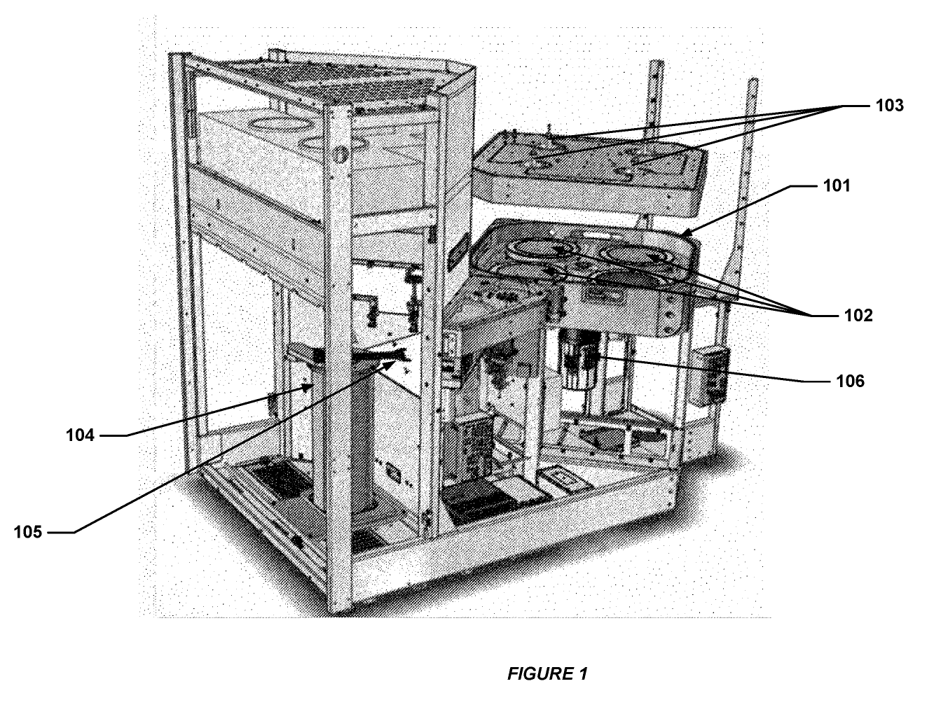

A typical system for chemical vapor deposition is shown in FIG. 1, having various tooling used to streamline and automate the deposition process on a series of wafers. A typical chemical vapor deposition (CVD) system has a process chamber 101 that generally has a circumferential interior wall that encircles a wafer pedestal 102 that is designed to support a semiconductor wafer during processing. The process chamber also typically includes a gas distribution system 103, or showerhead, that is positioned above the semiconductor wafer and the wafer pedestal and is configured to flow semiconductor processing gases across the semiconductor wafer in a generally evenly-distributed manner. In some embodiments, electrodes in the wafer pedestal and the showerhead (the showerhead itself may be made of metal and used as the electrode) may subject process gases trapped between the semiconductor wafer and the showerhead to a high voltage charge, thus causing a plasma to form within the gap between the semiconductor wafer and the showerhead.

During processing, a semiconductor wafer may be introduced into the processing chamber by a wafer handling robot 104. The wafer handling robot may typically include a blade- or spatula-type end effector 105 that is designed to support the semiconductor from below. The wafer pedestal may include a plurality of “lift pins” that are designed to be extended upwards from the surface of the wafer pedestal. The lift pins may be used to support the semiconductor wafer while the end effector is removed from, or inserted, beneath the semiconductor wafer. Once the end effector is clear of the semiconductor wafer, the lift pins may be retracted and the semiconductor wafer may be lowered onto the wafer pedestal. In a multi-station semiconductor processing tool, e.g., a single chamber that houses four processing stations (as depicted in FIG. 1), each with its own pedestal and showerhead, it may be necessary to move semiconductor wafers between processing stations within the chamber. In some multi-station semiconductor tools, an indexer may be used to simultaneously move multiple semiconductor wafers between multiple stations. Such indexers may include a set of lift arms that include pins or other features that are designed to contact the underside of the semiconductor wafer near the outer edge of the wafer and lift the wafer off of the pedestal on which it rests. Once all of the wafers have been lifted off of their respective pedestals by the indexer lift arms, the lift arms may be rotated in unison (they are often all part of one structure and lift/rotate as a group as in the case of a servo spindle 106), and the wafers may then be lowered onto different pedestals than they were on before the indexing occurred.

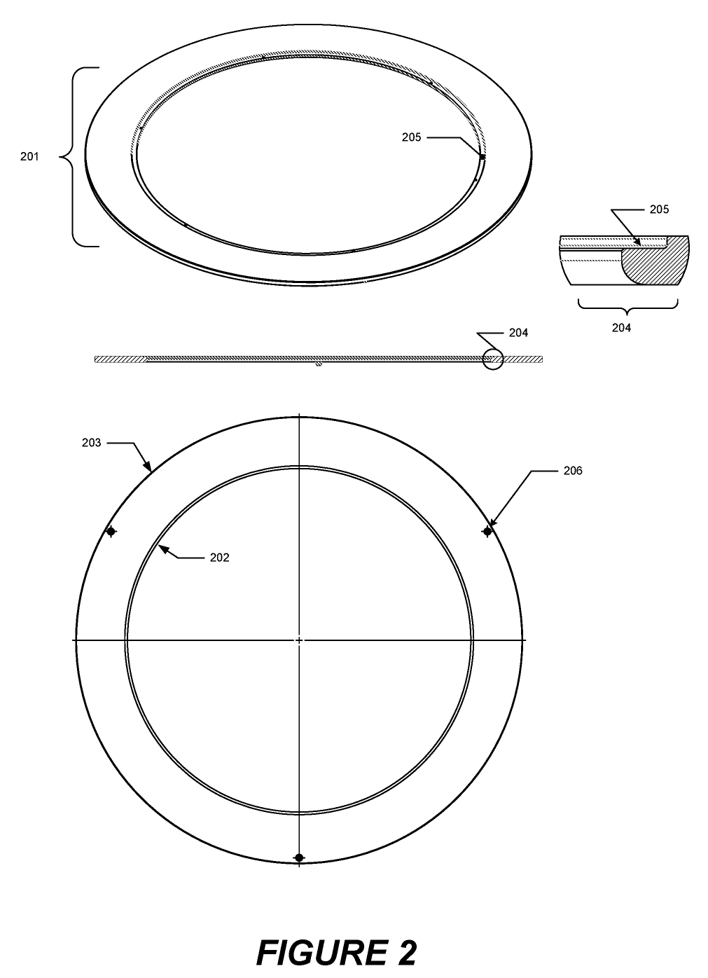

In order to prevent non-uniformities from developing in the semiconductor wafer in the vicinity of the indexer contact points, it is common to support the semiconductor wafer with an annular carrier ring (herein also referred to as an annular ring). FIG. 2 depicts a 300 mm carrier ring. An isometric view of the carrier ring 201 depicts the top surface of the ring that supports the semiconductor wafer continuously about the periphery of the semiconductor wafer. The carrier ring may act as a bridge between the semiconductor wafer and the indexer, i.e., the indexer contacts and lifts the carrier ring and the carrier ring, in turn, contacts and lifts the semiconductor wafer. In some cases, a carrier ring may include indexing pins 206 which engage with corresponding female features on a pedestal to prevent rotation of the carrier ring relative to the pedestal and center the ring on the pedestal.

The carrier ring, which is typically made of a ceramic material, is generally axially symmetric, and has an inner diameter 202 which is only slightly smaller, e.g., 3 mm-4 mm smaller or less, than the nominal outer diameter 203 of the semiconductor wafer it is designed to support. Thus, for a 300 mm semiconductor wafer, which is approximately 11.8 in in diameter, the corresponding carrier ring may have an inner diameter 202 of approximately 292 mm or 293 mm. Such a carrier ring may also have a circular recess 205 (shown in the enlarged view 204) in it that is slightly larger, e.g., approximately 0.03 in larger, than the semiconductor wafer diameter. This recess may have a depth that is nominally the same as the semiconductor wafer thickness, such that the semiconductor wafer top surface is nominally even with the top surface of the carrier ring when carried by the carrier ring. Carrier rings generally travel with the same semiconductor wafer during the semiconductor wafer's residence within the tool, and are generally made from a ceramic material, such as AlO₂ (aluminum oxide), silicon oxide, silicon carbide, silicon nitride, or aluminum nitride. Generally speaking, the outer diameter 203 of the carrier ring may be sized to be approximately the same size as the wafer pedestal outer diameter. For a 300 mm wafer, this diameter 203 may be approximately 380 mm, such that the carrier ring acts to “increase” the outer diameter of the semiconductor wafer by 20%-30%.

In some cases a carrier ring may additionally have one or more wafer orienting features that fix the orientation of a wafer, using flats or notches cut into one or more sides of the wafer, in the carrier ring. Common examples of wafer orienting features include pins, extrusions, or flats in the circular recess 205.

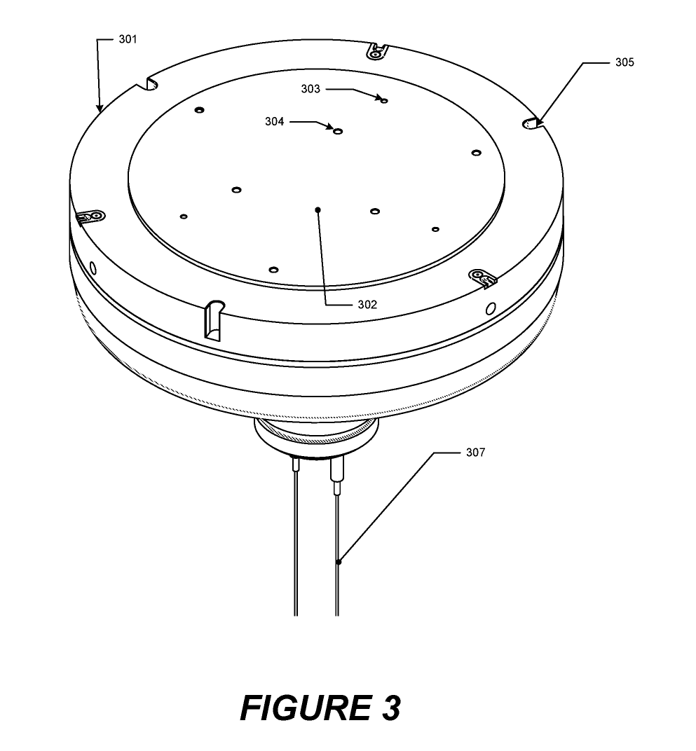

A typical 300 mm pedestal is shown in FIG. 3. The wafer pedestal is typically sized to have an outer diameter 301 to match the outer diameter of the carrier ring, e.g., approximately 380 mm in this case (or vice-versa). A pedestal also includes a mesa feature 302 which is a shallow, raised boss that is sized slightly smaller in diameter than the inner diameter of the respective carrier ring, in this case, 292 mm to 293 mm. When the carrier ring is lowered onto the pedestal, the mesa feature protrudes through the center opening of the carrier ring and lifts the wafer off of the carrier ring by a small amount, e.g., hundredths of an inch. The mesa feature may include lift pins 303 that may be raised and used to support the semiconductor wafer while an end effector is removed from, or inserted, beneath the semiconductor wafer. The mesa feature may also include low-contact area features, such as sapphire contact balls 304, that serve as mechanical interface between the wafer and the mesa feature when the lift pins are retracted; this reduces the amount of contact area that the wafer has with the pedestal. In both cases, the mesa feature generally has the same diameter as the wafer that is processed using a particular pedestal (although it is, of course, slightly smaller since it must fit within the inner diameter of the carrier ring). In a typical process chamber in which carrier rings are used, the pedestal may additionally have a series of recessed slots 305 or other clearance features to allow the portions of the indexer that are designed to lift the carrier ring/wafer off the pedestal to travel vertically from a point located below the carrier ring/wafer until those portions contact the wafer. Also shown in the figure are feed cables 307 which enable electrical signals to be sent to the pedestal electrode for controlling the plasma discharge and/or for controlling a heater within the pedestal during deposition.

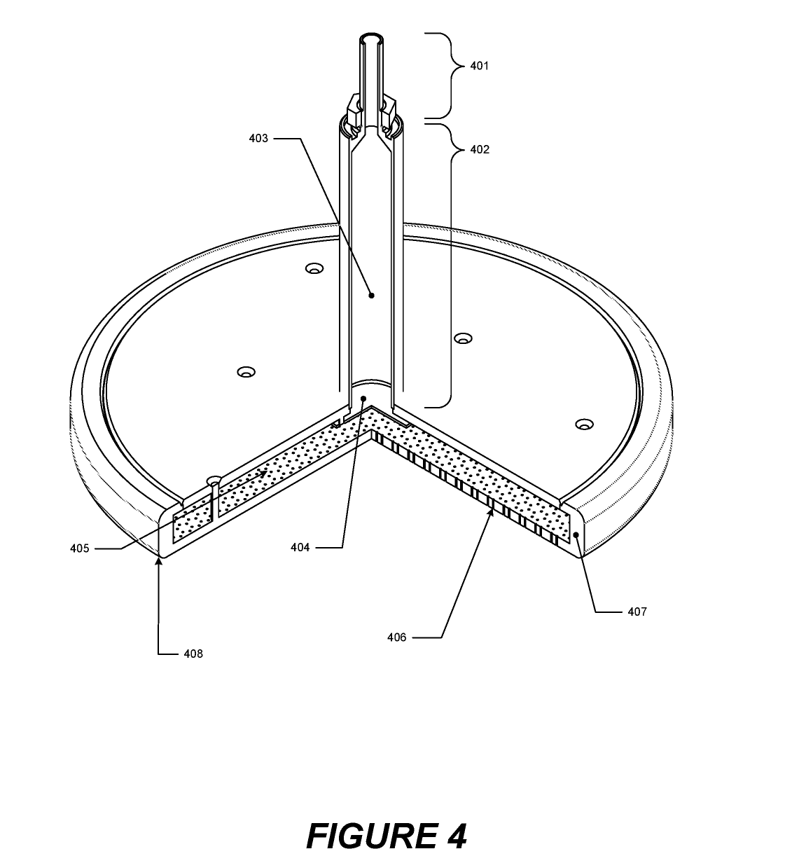

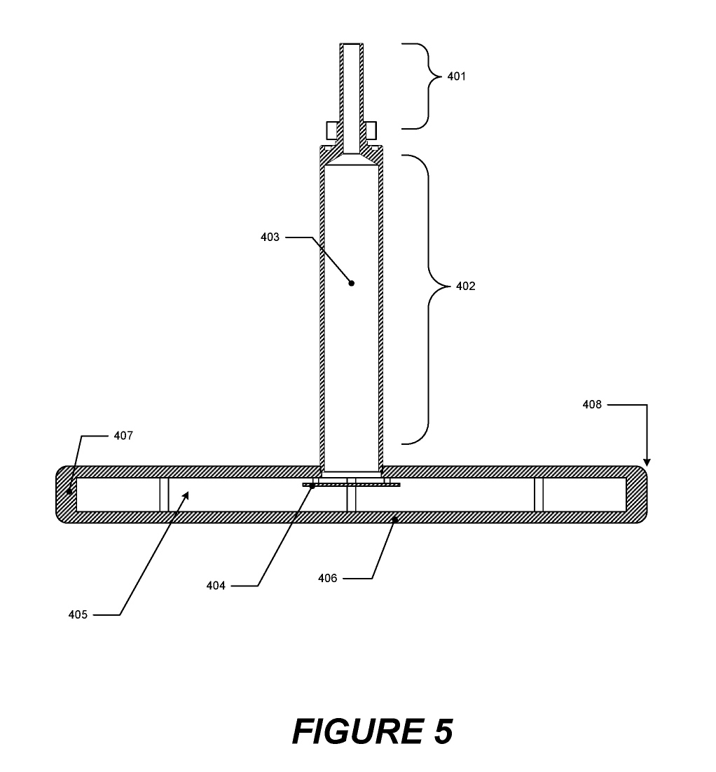

As mentioned above, in addition to the wafer pedestal and the carrier ring, a PECVD process chamber may also include a showerhead that is used to distribute process gases across the semiconductor wafer. FIGS. 4 and 5 depict a typical 300 mm showerhead. Semiconductor processing gas may enter the showerhead at the inlet 401 and travel down the stem 402 through a gas passage 403 after which the semiconductor processing gas may encounter a baffle plate 404 that redirects the gas to flow out radially into the plenum 405 (the interior space of the showerhead). Such showerheads are typically axially symmetric in overall shape and have a bottom surface 406, also referred to as a showerhead surface, which includes a large pattern of gas distribution holes that are arranged to distribute the semiconductor processing gas across the semiconductor wafer. This pattern of gas distribution holes may be generally evenly distributed across an area that is coextensive with the entire upper surface of the semiconductor wafer, i.e., the pattern of gas distribution holes may be distributed generally evenly across a circular area of the bottom of the showerhead that is nominally the same diameter as the semiconductor wafer. The showerhead is typically sized slightly larger than this diameter in order to accommodate the outermost side wall 407 of the showerhead. The outermost side wall 407 of the showerhead may be, for example, approximately 0.5″ thick. Thus, for a 300 mm semiconductor wafer, the showerhead may have an outer diameter 408 of approximately 330 mm (the semiconductor wafer diameter)+approximately 1 inch. Generally speaking, the showerhead diameter 408 may be kept within 80% or more of the diameter of the wafer pedestal.

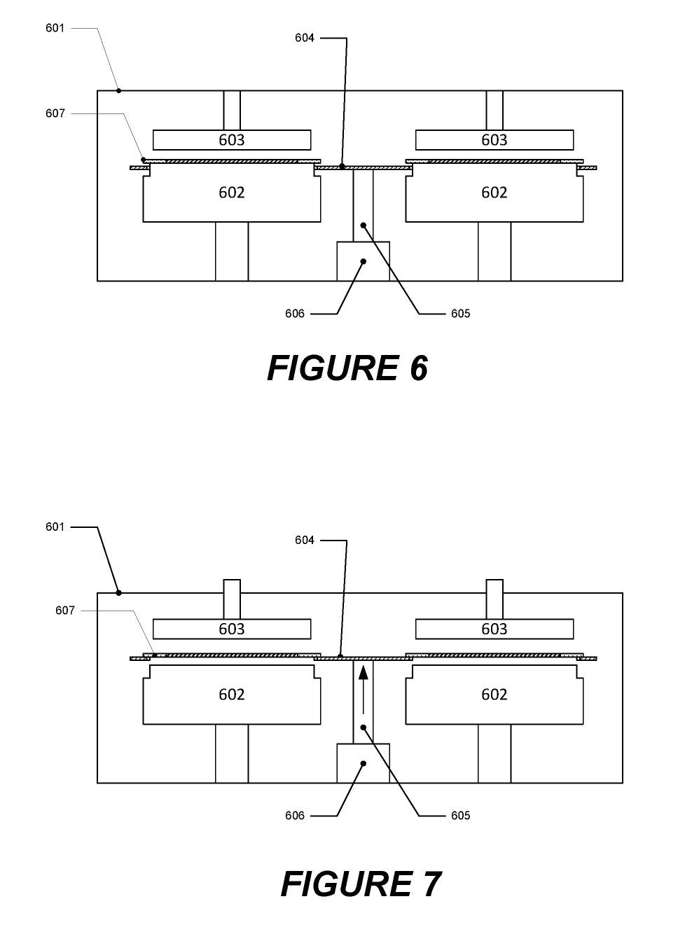

FIG. 6 shows a cross-section of a four-station process chamber 601 with pedestals 602 and showerheads 603. This depiction shows the carrier rings 607 in a stowed position in which they rest on the pedestals. Also depicted is an indexer which may be used to simultaneously lift and/or rotate the carrier rings 607 (and any wafers they may be carrying) from station to station. The indexer in this example is made of a plate 604 that lifts the carrier rings 607, a rotational shaft 605, and a lift mechanism 606 which is shown in its lowered position.

FIG. 7 shows a cross-section of the process chamber 601 from FIG. 6 with the carrier rings 607 in a lifted position prior to being rotated by the indexer. The lift mechanism 606 is shown in its raised position in this view.

The present inventors have determined that semiconductor processing tools such as the above-described 300 mm PECVD tool may, through the judicious replacement and/or modification of certain components, be modified to allow for processing of 200 mm semiconductor wafers in addition to 300 mm semiconductor wafers. In particular, the present inventors determined that such techniques and components may be especially applicable in the context of a Vector F47 and/or Vector Express platform 300 mm semiconductor processing tool, such as is produced by Lam Research Corp., to allow such a 300 mm tool to be used to process 200 mm wafers.

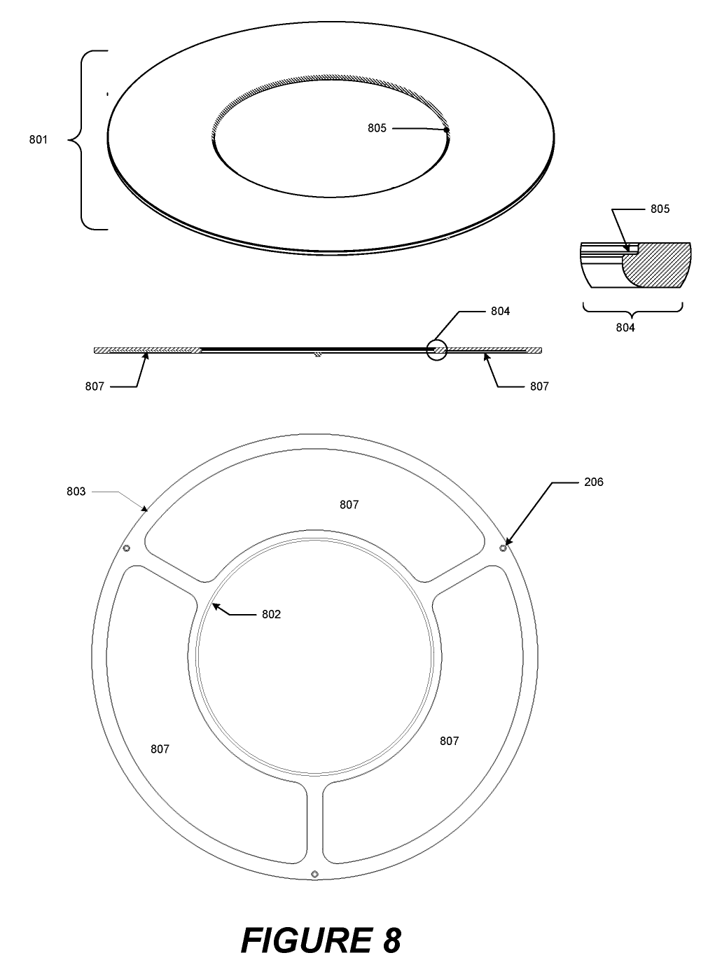

Due to the smaller size of the 200 mm semiconductor wafers, the carrier ring for the 300 mm semiconductor wafers cannot be used, as the 200 mm semiconductor wafer is smaller than the innermost diameter of the 300 mm carrier ring and cannot be supported by the 300 mm carrier ring. Accordingly, a replacement carrier ring, shown in FIG. 8, sized to fit a 200 mm semiconductor wafer may be used instead. The 200 mm carrier ring may have approximately the same outer diameter 803 as the 300 mm carrier ring, e.g., approximately 380 mm, so as to be able to be carried by the same indexer and used with a pedestal of the same diameter. Typically the outer diameter of a 300 mm carrier ring will be about 20% to 30% larger than a 300 mm wafer, i.e., a 200 mm carrier ring for use in a hybrid 200 mm/300 mm semiconductor processing tool will have an outer diameter that is approximately 80% to 95% larger than the 200 mm wafer diameter (as compared with the typical inner/outer diameter ratios of carrier rings, which, as noted earlier, involve outer diameters that are typically only 20% to 30% larger than the inner diameters and/or wafer diameters of the wafers such rings carry). While the 200 mm carrier ring typically has an outer diameter corresponding to that of a 300 mm carrier ring, it may have an inner diameter 802 that is sized slightly smaller than the outer diameter of the 200 mm semiconductor wafer, e.g., between approximately 198 mm and 199 mm. The 200 mm carrier ring may have a recess 805 (shown in detailed view 804) similar to that of the 300 mm carrier ring, e.g., a recess that is 1 mm to 2 mm larger than the interior diameter of the 200 mm carrier ring, for example. In some embodiments, the 200 mm carrier ring may have the same overall thickness and recess depth as a typical 300 mm carrier ring. For example, a thickness between about 1 mm and 10 mm and/or a recess depth between about 0.5 mm and 1 mm.

In addition to the different outer diameter/inner diameter ratio discussed above, another key difference between the two carrier rings in some embodiments is that the 200 mm carrier ring may include one or more other recesses 807 on the opposite side of the carrier ring from the circular recess that supports the semiconductor wafer, i.e., the side that faces the pedestal. These one or more recesses may be evenly and/or radially distributed about the center of the carrier ring such that the carrier ring maintains a center of mass that is located generally at the center of the carrier ring. For example, each recess may be an annular sector-shaped recess, e.g., having inner and outer arc-shaped walls with center points near or on the center point of the carrier ring, and radial walls that are generally parallel to radii of those arc-shaped walls; the intersections of such walls may have rounded or filleted corners or may be sharp-cornered. The thickness of the carrier ring may be approximately 50% of the nominal thickness of the carrier ring in the area of these recesses, e.g., 0.09 in instead of 0.18 in. The one or more recesses may occupy most of the back side of the carrier ring, although the recesses may not extend all the way to the inner or outer diameter of the carrier ring. By including such recesses, the weight of the depicted embodiments of the 200 mm carrier ring may only increase by approximately 20% over the weight of the 300 mm carrier ring depicted earlier (assuming the same material is used for both), although the area of the topmost surface of the 200 mm carrier ring is 88% larger than the area of the topmost surface of the 300 mm carrier ring. It is to be understood that even this 20% increase in weight of the carrier ring may ultimately result in an even lower weight increase in the carrier ring+wafer since the 200 mm wafer will generally be much lighter than a 300 mm wafer. Whatever weight increase is present in the carrier ring may thus be offset, at least partially, by a decrease in the wafer weight.

By including the one or more recesses 807 in the back side of the 200 mm carrier ring, the 200 mm carrier ring weight may be kept close enough to the 300 mm carrier ring weight that the same wafer handling routines for moving the wafers with the indexer may be used regardless of which carrier ring, the 200 mm or the 300 mm, is used.

For example, when semiconductor wafers are moved from station to station, the movement of the indexer may be carefully controlled to avoid over-high accelerations that may cause the carrier rings to slip with respect to the indexer (if they slip, they may get damaged or may not be correctly centered when lowered onto a pedestal). By preventing the carrier ring weight from changing drastically, e.g., by maintaining the 200 mm carrier ring weight within ^{˜}20% of the 300 mm carrier ring weight, the same motion profiles may be used with either carrier ring, thus eliminating any need for reprogramming the motion profile of the indexer depending on the size of the semiconductor wafer.

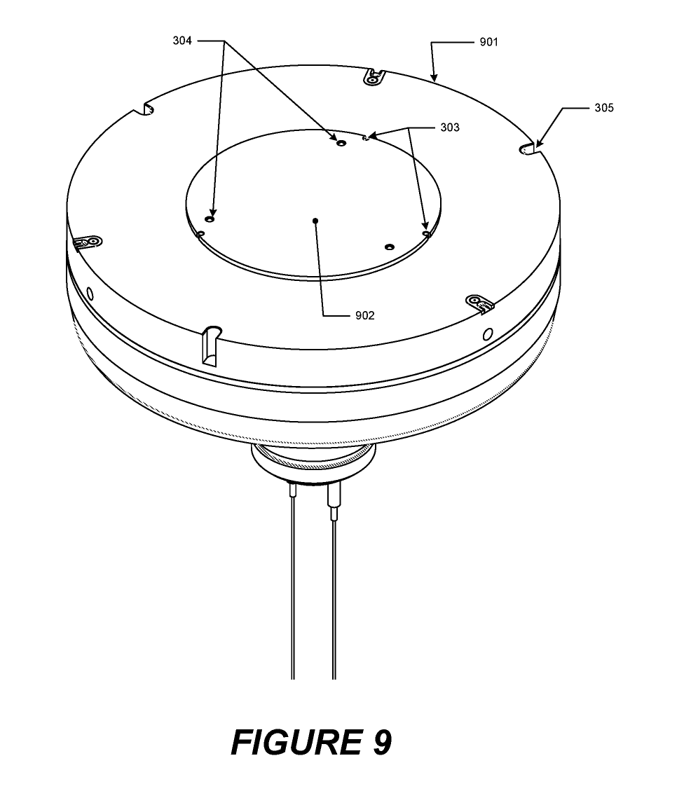

Another difference between the equipment used for 300 mm and 200 mm processing is that the 200 mm pedestal, depicted in FIG. 9, may have a smaller “mesa” feature on the top surface which allows a 200 mm wafer to be lifted from the smaller inner diameter of a 200 mm carrier ring; a pedestal with a mesa feature for a 300 mm wafer would be too large to fit within the reduced inner diameter of a 200 mm carrier ring. Correspondingly, while a mesa feature sized for a 200 mm wafer would fit within the inner diameter of a 300 mm carrier ring, using such a mesa feature to support a 300 mm wafer would result in over 50% of the 300 mm wafer being unsupported, which would cause the wafer to bow or bend, as well as uneven heat transfer and localized electrical field effects that would affect wafer processing uniformity. To provide compatibility with indexers and other robotic equipment designed to interface with a 300 mm carrier ring, features and dimensions of a 200 mm pedestal other than the mesa features and other features that are located within the mesa features, e.g., lift pin locations, may be designed to match those of a 300 mm pedestal. For example, a 200 mm pedestal 901 may have an outer diameter, recessed slots 305, or other clearance features matching that of a 300 mm pedestal which allow the portions of the indexer that are designed to lift the carrier ring/wafer off the pedestal to travel vertically from a point located below the carrier ring/wafer until those portions contact the wafer. This helps mitigate changes in free volume within the process chamber that may result from swapping 200 mm hardware with 300 mm hardware or vice versa.

The components that may be swapped into and out of a 300 mm tool, such as is described above, in order to transform it into a 200 mm tool may be designed with an interest in preserving the overall free volume of the semiconductor process chamber. By maintaining (or attempting to maintain) the overall free volume of the semiconductor process chamber, regardless of whether 200 mm or 300 mm wafers are being processed, the potential for undesirable changes to gas flow paths and pressure distributions within the chamber is reduced. To this end, in some implementations, the outer diameter of a 200 mm pedestal 901 may be chosen to closely align with that of a 300 mm pedestal, in part, to reduce changes in gas flow paths and pressure distributions within the process chamber. Another benefit to retaining a pedestal outer diameter that is similar to the pedestal outer diameter for a 300 mm pedestal is that the same indexer system may be used in both 200 mm wafer processing and 300 mm wafer processing. In other implementations, however, a pedestal with an outer diameter sized for 200 mm wafers may be used, e.g., a pedestal with an outer diameter of approximately 230 mm to 260 mm, and the indexer may be replaced or modified such that the wafer lifting features of the indexer are positioned so as to engage with a carrier ring of similar outer diameter to the pedestal.

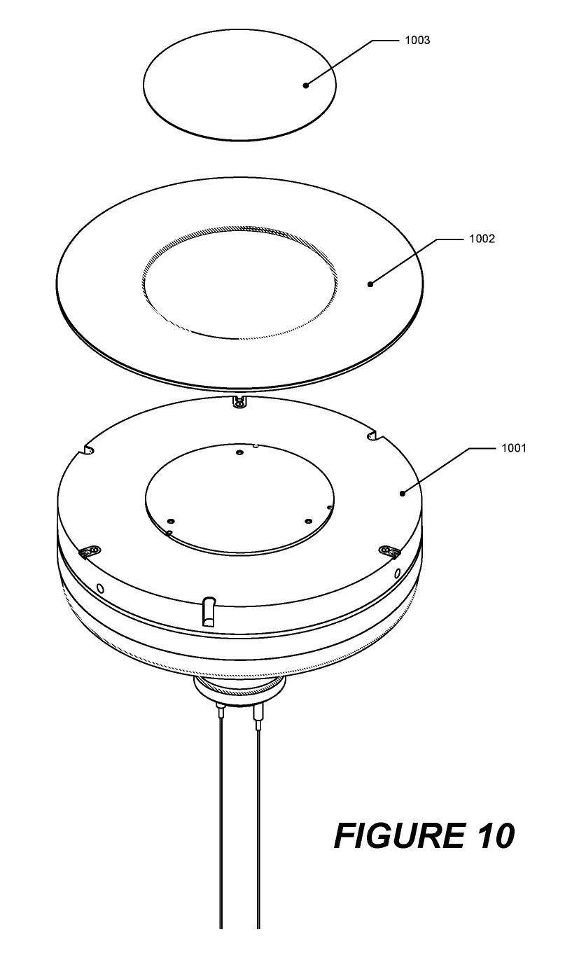

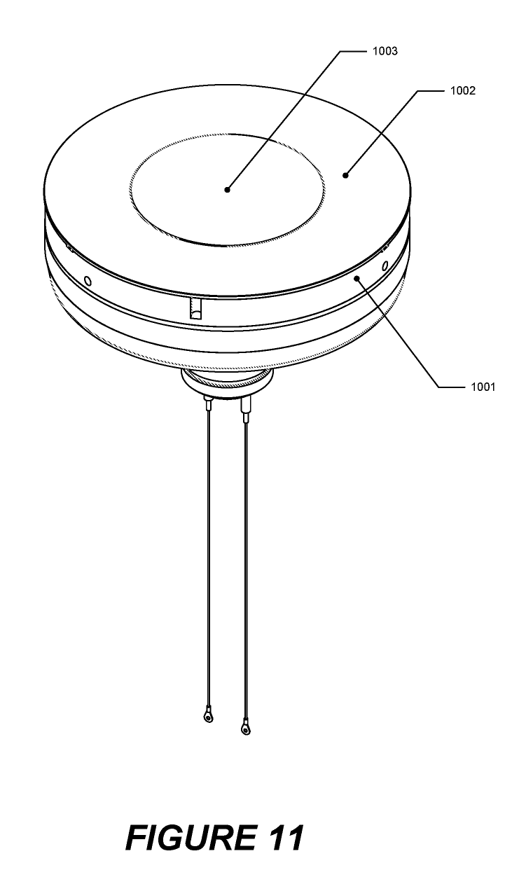

FIG. 10 depicts an exploded view of how a 200 mm pedestal 1001, a 200 mm carrier ring 1002, and a 200 mm wafer 1003 interface with each other. FIG. 11 provides a collapsed view of the arrangement, which depicts how these components would appear together in a process chamber.

FIG. 12 depicts a four-station arrangement with an indexer having a plate 1204 and a rotary hub 1205 that has been lowered, thus leaving the 200 mm carrier rings 1002 on their respective pedestals 1001. Wafers 1003 are supported on the contact balls in the mesa feature of each pedestal. Showerheads are not shown in this figure, but would be located above each station/pedestal.

FIG. 13 depicts the four-station arrangement of FIG. 12, but with the rotary indexer plate 1204 raised, lifting the carrier rings 1002 on the leftmost two pedestals 1001 clear of the pedestals. The other two carrier rings have been shown left on their pedestals to allow lifting features/contact points 1306 of the indexer to be more clearly seen, but would also be lifted in the same operation using contact points 1306 which fit into recesses in the respective pedestals 1307. The 200 mm wafer for the rear left station has been lifted up with the rear. Once clear of the pedestals, the indexer, carrier rings, and wafers may be rotated in 90 degree increments until the wafers reach their desired stations, and then the indexer may lower the carrier rings and wafers back down onto the pedestals.

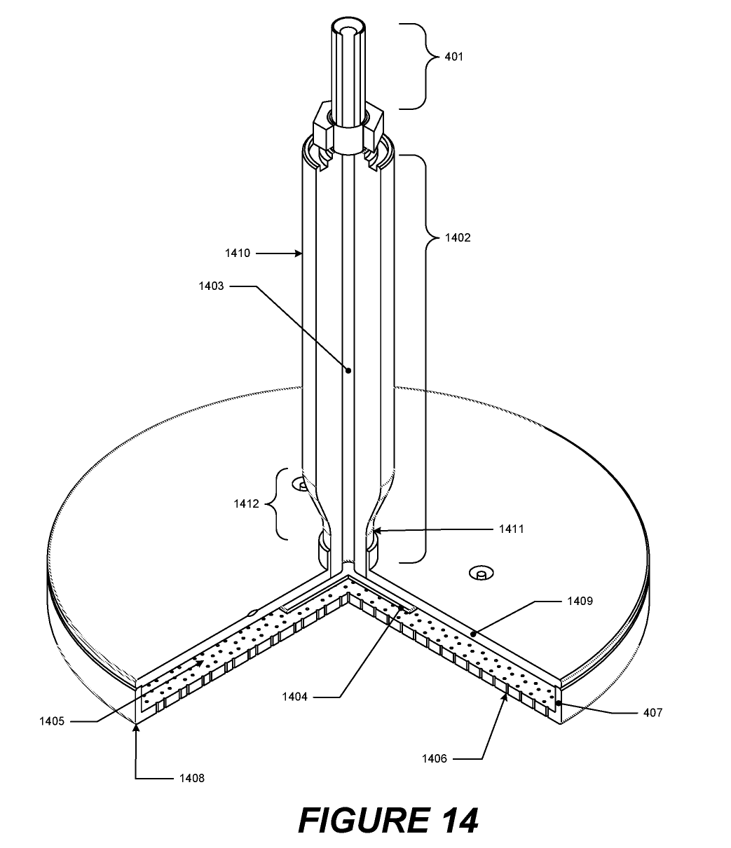

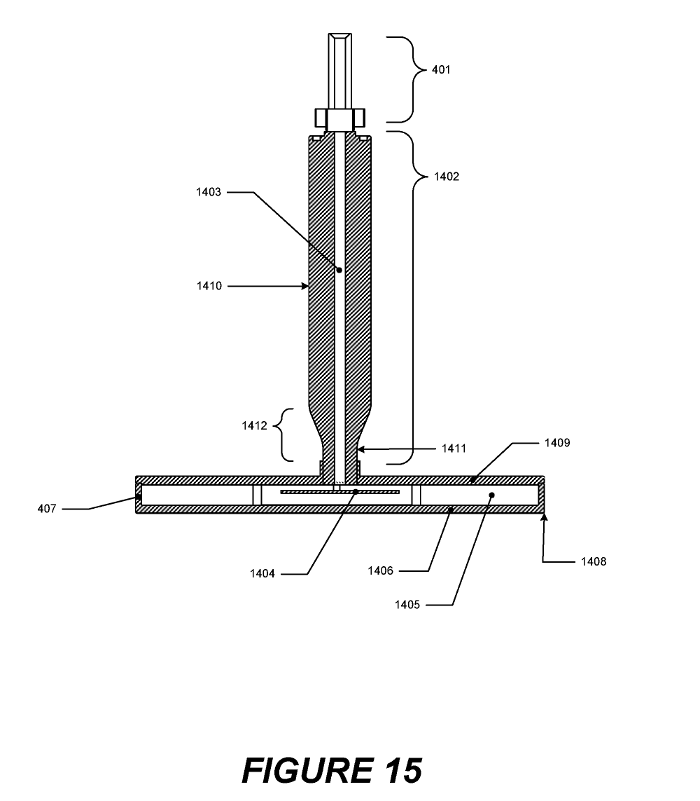

In addition to the use of a modified carrier ring and modified pedestals, the present inventors determined that the showerhead that is used with the 300 mm wafers would need to be replaced with a showerhead having a different diameter, shown in FIGS. 14 and 15, in order to process 200 mm semiconductor wafers with acceptable uniformity characteristics. 200 mm showerheads typically have an outer diameter 1408 that is in the range of 50% to 70% to the wafer pedestal 901 diameter. In some embodiments, the showerhead diameter for 200 mm wafer processing may be approximately 60% of the pedestal diameter, as compared to a 300 mm showerhead, which may have an outer diameter that is greater than the wafer pedestal diameter, e.g., 110% of the wafer pedestal diameter.

During development, the present inventors determined that while the 300 mm showerhead was certainly capable of evenly distributing process gases across a 200 mm semiconductor wafer, the interaction between the 300 mm showerhead and the increased surface area of the carrier ring for a 200 mm wafer nonetheless caused wafer non-uniformities that were not present in 300 mm wafers processed using the same equipment. In a PECVD system, it is common for the pedestal and the showerhead to serve as opposing electrodes in a plasma generation system. By inducing a voltage difference between the showerhead and the pedestal, process gas that is present within the chamber and, in particular, between the pedestal and the showerhead may be caused to form a plasma that is used to enhance deposition (thus, the moniker “Plasma-Enhanced Chemical Vapor Deposition,” or PECVD). Unfortunately, due to the increased surface area of the 200 mm carrier ring, the deposition operations performed using such a plasma were enhanced and greater deposition of material occurred towards the edges of the semiconductor wafers than near the center.

The present inventors determined that a reduced-footprint showerhead would reduce the interaction between the showerhead and the carrier ring. Subsequent testing with a showerhead having a diameter of 60% of the diameter of the pedestal revealed an immediate and marked improvement in wafer uniformity.

Like the 300 mm showerhead in this example, the 200 mm showerhead is a “chandelier” style showerhead, i.e., it is suspended from above within the chamber by way of a “stem” 1402, which is a thin supporting member that extends from the top surface of the showerhead and through a seal in the chamber ceiling. The stem is typically moveable in the vertical direction to allow the showerhead height with respect to the semiconductor wafer to be adjusted. The stem is typically hollow and includes an internal passage or passages 1403 for supplying gas to the showerhead. As with 300 mm showerheads, a circular baffle plate of a 200 mm showerhead 1404 may be suspended within the plenum 1405 of the showerhead, centered on the stem inlet into the plenum, and offset from the back plate 1409 of the showerhead by some distance. Semiconductor process gas that flows into the plenum from the stem will strike the baffle plate and be forced to flow in a radial direction instead of an axial direction. The baffle plate may be offset from the upper interior wall of the plenum by a plurality of spacers or standoffs that may be connected to the back plate 1409 of the showerhead by screws or other fasteners. After gas reaches the plenum it may then be routed through gas distribution holes in the showerhead surface 1406 and onto the surface of the wafer, after which it flows across the surface of the wafer in a radial direction.

The 200 mm showerhead may have an interior stem diameter 1403, e.g., gas flow passage diameter, that is considerably smaller in diameter than that of the 300 mm showerhead, e.g., ^{˜}0.25 in as opposed to ^{˜}1.2 in, since the amount of gas flow needed to process 200 mm wafers is much less than that needed to process 300 mm wafers. In most chandelier showerheads, the stems may have a relatively thin wall, e.g., a thickness on the order of 5%-10% of the outer diameter of the stem.

However, the stem of the 200 mm showerhead departs from this convention and retains the same nominal exterior diameter 1410 as the 300 mm showerhead allowing the 200 mm showerhead to interface with the same seal interface (which permits the showerhead to be translated up and down in the process chamber without comprising the chamber environment) as the 300 mm showerhead within the process chamber. In some embodiments the outer diameter 1410 may be between 32 mm and 38 mm, and in a particular embodiment the diameter is about 35 mm, e.g., 35 mm ±0.5 mm. As a result, the wall thickness of the 200 mm showerhead stem in the depicted example is approximately 40% of the outer diameter of the stem, e.g., a 0.56 in wall thickness and a 1.37 in outer diameter. Generally speaking, the wall thickness of such stems may be on the order of 30% or more of the outer diameter of the stem for most of the stem length.

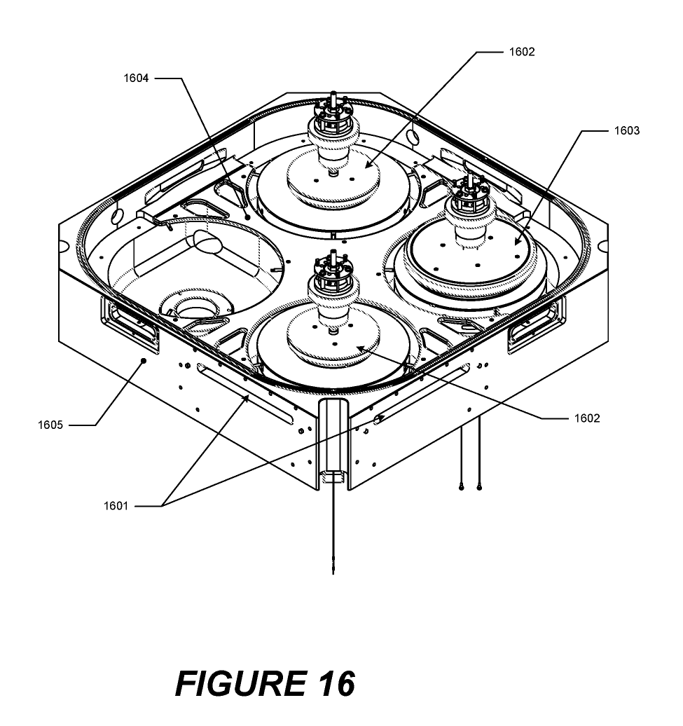

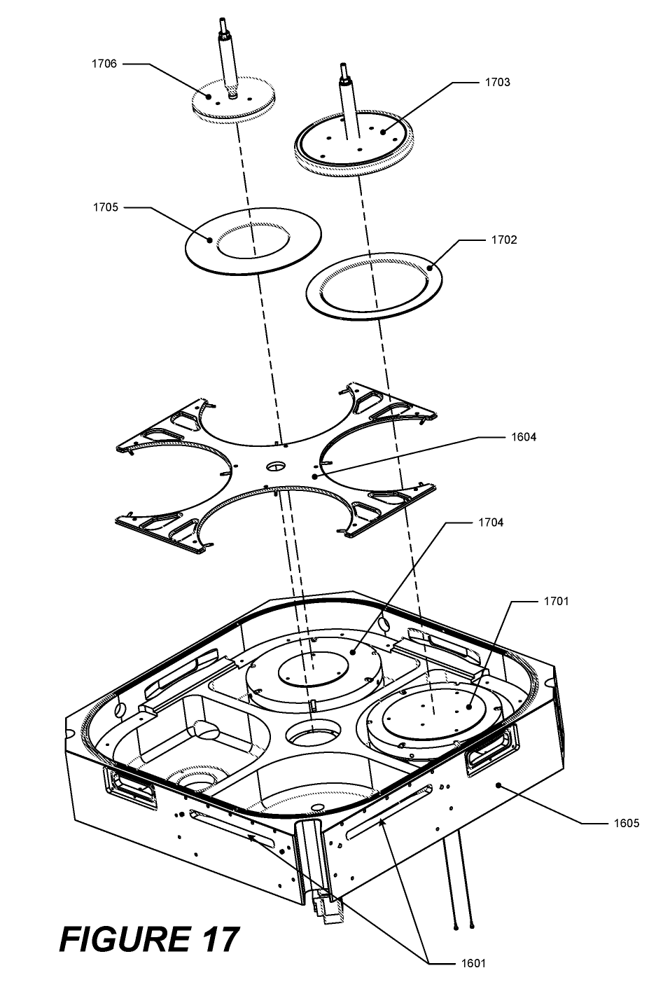

The 200 mm showerhead stem may also differ from the 300 mm showerhead stem in that the 200 mm showerhead stem may not have a cylindrical outer surface along the entirety of its length. In particular, the 200 mm showerhead stem may transition from a nominal exterior diameter 1410, e.g., ^{˜}1.37 in, to a reduced exterior diameter 1411, e.g., ^{˜}0.75, as the stem nears the showerhead itself. Thus, for example, the 25% or so of the stem adjacent to the showerhead may include a tapered section 1412 that necks the stem diameter down from its nominal exterior diameter to a much smaller diameter, e.g., a diameter on the order of 50%-70% of the nominal exterior diameter. This tapered section may have rounded transitions where it joins the cylindrical surfaces of the stem. Such a tapered section may be included to accommodate features on the back plate 1409 of the showerhead that might be occluded or difficult to access were the stem to retain the nominal exterior diameter all the way to the back plate. The transition between the cylindrical and tapered sections may be blended or otherwise prevented from having a sharp edge to minimize the potential for high-voltage arcing between the stem and other structures in the chamber. FIG. 16 shows a four-station processing chamber 1605 in which the top of the processing chamber is not shown. The processing chamber includes load ports on the chamber wall 1601 that are greater than 300 mm in width, e.g., ^{˜}330 mm to 340 mm (approximately 10%—this may allow margin for wafer misplacements, etc.), to allow both 200 mm wafers and 300 mm wafers to be transferred into and out of the chamber. In a typical 200 mm processing chamber, such load ports would not large enough to accommodate a 300 mm wafer. As shown, the processing chamber has three installed stations (a fourth is empty), each of which includes a pedestal, a carrier ring, and a showerhead. Of the three stations depicted, two are 200 mm stations 1602, and one is a 300 mm station 1603. The processing chamber also includes a rotary indexer 1604 that can interface with both the 200 mm wafers and the 300 mm wafers.

Figure QQ shows an exploded view of a four-station processing chamber 1605 in which the top of the processing chamber is not shown. The processing chamber is depicted with one 300 mm station having a 300 mm pedestal 1701, a 300 mm carrier ring 1702, and a 300 mm showerhead 1703. The processing chamber is also depicted with a 200 mm station having a 200 mm pedestal 1704, a 200 mm carrier ring 1705, and a 200 mm showerhead 1706. The station includes a rotary indexer 1604 that is capable transferring 200 mm and 300 mm carrier rings holding wafers between each of the four station locations.

Typically all stations in such a processing chamber will have pedestals, carrier rings, and showerheads made to work with the same wafer size. For example, a four-station processing chamber will typically include either four 300 mm stations or four 200 mm stations.

It is to be understood that the above-disclosed semiconductor processing tool allows for much of the same hardware to be used to process both 200 mm and 300 mm wafers. Such a tool offers an attractive option for manufacturers that currently produce predominantly 200 mm wafers. By purchasing a hybrid 200 mm/300 mm semiconductor manufacturing tool, such manufacturers may avoid having to scrap or sell large quantities of dedicated 200 mm tools if they later switch to manufacturing 300 mm wafers. Such flexibility, of course, may require some sacrifice in terms of the number of semiconductor processing tools that may be contained within a given fab, as the using such hybrid 200 mm/300 mm tools in place of dedicated 200 mm tools will result in a lower density of such tools in the fab due to the larger size of such tools.

In some embodiments, hybrid 200 mm/300 mm tools may be sold as off-the-shelf 200 mm/300 mm systems that include components specific to both 200 mm wafer processing and 300 mm wafer processing. In other embodiments, such tools may be sold with components generic to both 200 mm and 300 mm wafer processing, e.g., the chamber, controllers, etc., and with components specific to 200 mm wafer processing. In such embodiments, components specific to 300 mm wafer processing, e.g., 300 mm carrier rings, 300 mm showerheads, and 300 mm pedestals, may be sold separately as an upgrade kit or as replacement parts. It is also conceivable the components specific to 200 mm wafer processing may be sold as a retrofit kit for existing 300 mm processing tools. In such embodiments, the components specific to 200 mm wafer processing may be swapped out for their equivalent 300 mm components.

It is also to be understood that while the above discussion has focused on PECVD equipment, other types of semiconductor tools may be modified in a similar manner to allow for both 200 mm and 300 mm functionality in the same system.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

It is also to be understood that the claims may recite slightly different numerical values or ranges than are discussed above within the specification. Such cases represent additional potential ranges or values of such quantities, and are not to be viewed as conflicting with the above disclosure, but rather as augmenting the above disclosure.

What is claimed is:

1. An apparatus for carrying semiconductor wafers, the apparatus comprising,
an annular ring that is between 1 mm and 10 mm thick and that has an outer diameter greater than 300 mm and an inner diameter less than 200 mm; and
one or more recesses in a first side of the annular ring, wherein:
the annular ring has a second side that is configured to support a semiconductor wafer, and
the second side is opposite the first side.

2. The apparatus of claim 1, wherein the thickness of the annular ring is less than 5 mm.

3. The apparatus of claim 1, further comprising a circular recess in the second side of the annular ring, wherein:
the circular recess and the annular ring are coaxial, and
the circular recess has a diameter greater than 200 mm.

4. The apparatus of claim 3, wherein the circular recess has a depth that is between 0.5 mm and 1.5 mm.

5. The apparatus of claim 3, wherein the circular recess has a diameter greater than 200 mm and less than 210 mm.

6. The apparatus of claim 1, wherein the apparatus is made of a ceramic material selected from the group consisting of: aluminum oxide, silicon oxide, silicon carbide, silicon nitride, and aluminum nitride.

7. The apparatus of claim 1, wherein the one or more recesses have annular sector shapes.

8. The apparatus of claim 1, wherein the outer diameter is between 360 mm and 390 mm.

9. The apparatus of claim 1, wherein the thickness of the annular ring in the one or more recesses is less than 50% of the thickness of the annular ring in locations adjacent to the one or more recesses.

10. A showerhead apparatus for distributing gases over a surface of a wafer, the showerhead apparatus comprising,
an inlet, wherein the inlet is configured to connect to a gas source;
a stem with an interior gas passage; and
a showerhead plenum, wherein:
the interior gas passage fluidically connects the inlet with the showerhead plenum,
the showerhead plenum has an outer diameter between 189 mm and 265 mm, thereby configuring the showerhead plenum to process 200 mm semiconductor wafers, and
the stem has a cylindrical portion with an exterior diameter that is sized to interface with a mechanical interface of a semiconductor processing tool, wherein the mechanical interface of the semiconductor processing tool is also sized to interface with a different showerhead configured to process 300 mm semiconductor wafers.

11. The showerhead apparatus of claim 10, wherein the stem has an exterior diameter of between 30 mm and 38 mm.

12. The showerhead apparatus of claim 10, wherein the stem has a tapered portion interposed between the showerhead plenum and the cylindrical portion and the stem tapers from a nominal exterior diameter of between 30 mm and 38 mm in the cylindrical portion to a diameter of between 16 mm and 24 mm.

13. The showerhead apparatus of claim 10, wherein the interior gas passage diameter is between 5 mm and 10 mm.

14. A semiconductor wafer processing tool comprising,
a chamber having one or more semiconductor processing stations, wherein:
at least one of the semiconductor processing stations has a pedestal and a showerhead, and
the pedestal has a raised wafer support surface with an outer diameter of less than 200 mm and greater than 150 mm; and
one or more load ports, wherein:
each load port is configured to allow 300 mm semiconductor wafers to be inserted into or withdrawn from the chamber,
the one or more load ports have a width greater than 300 mm, and
each load port is located in a wall of the chamber.

15. The semiconductor wafer processing tool of claim 14, wherein:
the pedestal has an outer diameter of at least 300 mm, and
the showerhead has an outer diameter between 50% and 70% of the pedestal outer diameter.

16. The semiconductor wafer processing tool of claim 14, wherein:
the pedestal and the showerhead are swappable with a second pedestal and a second showerhead,
the second pedestal has an outer diameter of at least 300 mm and a raised wafer support surface with an outer diameter of less than 300 mm and greater than 250 mm,
the second showerhead has an outer diameter that is 80% or more of the pedestal outer diameter, and
installing the second pedestal and the second showerhead in one or more of the semiconductor processing stations configures, at least in part, those semiconductor processing stations to process 300 mm diameter wafers.

17. The semiconductor wafer processing tool of claim 14, further comprising:
a rotational indexer shaft; and
a rotational indexer, wherein:
the rotational indexer shaft is configured to rotate the rotational indexer within the chamber, thereby allowing semiconductor wafers to be transferred from station to station within the chamber.

18. The semiconductor wafer processing tool of claim 17, wherein the at least one of the semiconductor processing stations further includes:
an annular ring that is between 1 mm and 10 mm thick and that has an outer diameter greater than 300 mm and an inner diameter less than 200 mm, wherein each annular ring has one or more recesses in a first side of the annular ring.

19. The semiconductor wafer processing tool of claim 14, wherein each pedestal has an outer diameter of between 360 mm and 390 mm.

20. The semiconductor wafer processing tool of claim 14, wherein the showerhead has an outer diameter of between 189 mm and 265 mm.
